(19) United States
(12) Patent Application Publication
(10) Pub. No.: US 2026/0282618 A1
(43) Pub. Date: Sep. 17, 2026

(54) EMISSIVE METASURFACE FOR EFFICIENT COLOR CONVERSION

(71) Applicant: Sony Semiconductor Solutions Corporation, Kanagawa (JP)

(72) Inventors: Nikolaus KNORR, Stuttgart (DE); Tzenka MITEVA, Stuttgart (DE); Max STRAUSS, Stuttgart (DE); Paul Georg HEIMEL, Stuttgart (DE); Berthold WEGNER, Stuttgart (DE); Aleksandr VASKIN, Stuttgart (DE)

(73) Assignee: Sony Semiconductor Solutions Corporation, Kanagawa (JP)

(21) Appl. No.: 19/167,852

(22) PCT Filed: Jan. 31, 2024
(86) PCT No.: PCT/EP2024/052417

§ 371 Date: Sep. 23, 2025

(30) Foreign Application Priority Data
Mar. 31, 2023 (EP) 23166244.6

(51) Int. Cl. H10H 20/851; H10H 20/855

(52) U.S. Cl. CPC H10H 20/8514; H10H 20/855

(57) ABSTRACT

An emissive metasurface comprising a nanostructured dielectric component and an emissive system, wherein the nanostructured dielectric component comprises a plurality of metaatoms, and wherein the emissive system is configured to absorb and emit light in the visible range, and wherein the metaatoms are configured so that they resonantly match with the frequency of the light absorbed and emitted by the emissive system, is disclosed herein.

### TECHNICAL FIELD

The present disclosure relates to the field of nanophotonics, in particular to metasurfaces, a method for making metasurfaces and a use of metasurfaces.

### TECHNICAL BACKGROUND

With the help of color filters/color conversion elements, for example color displays can be developed that only have a single-color (typically blue) light source. However, it is difficult to achieve efficient color conversion, blocking of the incident blue light, and directional control of the converted light.

It has been shown that emissive metasurfaces based elements greatly increase the conversion efficiency and brightness of the emitted light while suppressing the incident light in the emission direction. However, they may not be applicable at lower wavelengths due to strongly increasing absorption of the high refractive index materials such as silicon, that is typically used for such elements.

Metamaterials are engineered materials that interact with waves in a desired fashion. With metamaterials properties of the final product can be realized which are not possible with naturally occurring materials. Building blocks of the metamaterials are so-called meta-atoms, that are smaller than the wavelengths of desire. Metasurfaces are 2D metamaterials with a thickness below the wavelength of interest. They can be any arrangement in between, on the one hand, spatially highly inhomogeneous, with generally non-identical meta-atoms placed on a generally aperiodic lattice, and, on the other hand, essentially periodic with identical meta-atoms placed in a periodic lattice (including photonic crystal slab geometries). In general, the main distinguishing feature of metasurfaces as opposed to gratings and photonic crystals (both of their functions are defined by their periodic arrangements) is that metasurfaces dominantly inherit properties from their individual meta-atoms and their resonant properties. Metasurfaces are disclosed e.g., in Capasso et al., Science 2016 (352), 1190, Rivas et al., Light: Science & Applications 2013 (2), Nano Lett. c 2018 (18), 6906 and Vaskin et al., Nanophotonics 2019, 8(7), 1151. Meta-atoms are described e.g., in Belkin et al., Optica 2016 (3), 283.

Light-emitting metasurfaces are metasurfaces with nanoscale emitters such as quantum dots (QDs), dye molecules, or direct-bandgap semiconductors integrated into the metasurface architecture. The meta-atoms can be designed to act as nanoantennas that efficiently couple the emission from the excited metaatoms to the far-field, while imprinting the desired properties onto the emitted light field. To optimize the coupling between the nanoantennas and the emitters, the latter should be localized in optical near-fields of the nanoantennas. Light-emitting metasurfaces inherit most of the functionalities provided by optical nanoantennas, such as excitation enhancement and emission enhancement via the Purcell effect, as well as spectral and directional shaping of the emitted light. Emissive metasurfaces are disclosed e.g., in Vaskin et al., Nanophotonics 2019, 8(7), 1151.

Light-emitting materials are disclosed e.g., in US 20160102842A1. Fluorescent nanosensors are disclosed e.g., in US 20210015410A1 and EP2101175A1.

The influence of SiO₂/TiO₂ nanocomposites on dual resonance Forster energy transfer in ternary hybrid thin films is described e.g., in Al-Asbahi et al., Res. In Physics 2021, 24, 104142. The cooperative chirality and sequential energy transfer in a supramolecular light-harvesting nanotube is described in Ji et al., Angew. Chem. Int. Ed. 2019, 58, 844. High color-purity red, green, and blue-emissive core-shell upconversion nanoparticles using ternary near-infrared quadrature excitations are described e.g., in Jia et al., ACS Appl. Mater. Interfaces 2023, 13(3), 4402.

### SUMMARY

According to a first aspect there is provided an emissive metasurface comprising a nanostructured dielectric component and an emissive system, wherein the nanostructured dielectric component comprises a plurality of metaatoms, and wherein the emissive system is configured to absorb and emit light in the visible range, and wherein the metaatoms are configured so that they resonantly match with the frequency of the light absorbed and emitted by the emissive system. In a further aspect there is provided a semiconductor device comprising the metasurface as described herein, the metasurface being configured for enhancement of absorption of a first color and emission of a second color.

Further, there is provided a method for preparing a metasurface as disclosed herein, the method comprising the steps:
Providing a dielectric component,
Coating the dielectric component,
Texturing the coating,
Etching the dielectric component, and
Applying an emissive system on the thus obtained nanostructured surface.

### BRIEF DESCRIPTION OF THE DRAWINGS

Embodiments are explained by way of example with respect to the accompanying drawings, in which:

FIG. 1 shows an exemplary metasurface.

FIG. 2 shows a pattern of a dielectric component on a substrate.

FIG. 3 shows the Field Energy in the emissive system (normalized to unstructured system).

FIG. 4 shows the emission spectrum of a planar emissive film on an unstructured substrate.

FIG. 5 shows the topography of an emissive system evaporated on a nanostructured TiO₂ sample.

FIG. 6 shows the profile structure of a metasurface. FIG. 6a shows the measured profile structure and FIG. 6b shows the schematic profile structure of a metasurface.

FIG. 7 shows the measured and the simulated transmission spectra of a metasurface according to the present disclosure.

FIG. 8 shows metasurfaces vs. flat film emission correlation recorded by fluorescence microscopy.

FIG. 9 shows the angle-resolved measured emission based on reciprocity principle. FIG. 9a shows the flat to scale emission and FIG. 9b shows the flat to scale, normalized emission.

FIG. 10 shows an angle-resolved emission simulation based on the reciprocity principle.

FIG. 11 shows angle-resolved emission of a metasurface. FIG. 11a shows measured emission and FIG. 11b shows simulated emission.

FIG. 12 shows the measured angle-resolved emission of a metasurface and a flat reference.

FIG. 13 shows a method for preparing a metasurface.

FIG. 14 shows a method for preparing a dielectric component on a substrate.

FIG. 15 shows a section of the simulated electric field intensity distribution of an emissive metasurface.

FIG. 16 shows an exemplary LED color conversion filter.

FIG. 17 shows an exemplary semiconductor device.

### DETAILED DESCRIPTION OF EMBODIMENTS

Before a detailed description of the embodiments under reference of the figures is given, general explanations are made.

The embodiments disclose an emissive metasurface comprising a nanostructured dielectric component and an emissive system, wherein the nanostructured dielectric component comprises a plurality of metaatoms, and wherein the emissive system is configured to absorb and emit light in the visible range, and wherein the metaatoms are configured so that they resonantly match with the frequency of the light absorbed and emitted by the emissive system.

The emissive system may be at least partially in the near-field proximity to the nanostructured dielectric component.

The plurality of metaatoms may be arranged such that they support at least one lattice resonance mode and wherein the metaatoms may have a size and shape such that they support at one further resonance mode.

The metaatoms may for example be arranged in a lattice. The lattice may for example be a square lattice, a hexagonal lattice, or the like.

In an embodiment, the nanostructured dielectric component in the metasurface is configured so that a first localized (e.g., Mie) resonance mode of the metaatoms and a lattice resonance mode of the nanostructured dielectric component are matched to the emission frequency of the emissive system, and so that a second localized (e.g., Mie) resonance mode of the metaatoms is matched to the absorption frequency of the emissive system.

The emission frequency may for example relate to the peak output light emitted by the emissive system and the absorption frequency may for example relate to peak input light absorbed by the emissive system.

The nanostructured dielectric component and the emissive system may be configured to resonantly enhance the absorption of the emissive system, e.g., at low wavelengths.

The nanostructured dielectric component and the emissive system may be configured to resonantly enhance the emission of the emissive system

In an embodiment, the nanostructured dielectric component and the emissive system are configured to perform emission at longer wavelengths with overall low absorption losses.

The emissive metasurface may be configured for color conversion in the visible spectrum. In this way, the metasurface may for example be applied as a LED color conversion filter. For example, the emissive system may be configured to provide a ternary or higher order emissive energy transfer system for efficient metasurface based color conversion. The metasurface may in particular provide an efficient wide wavelength gap color conversion. The emissive metasurface may for example be configured for up-conversion and/or down-conversion.

There are embodiments, wherein the emissive metasurface is configured for directional intensity control of emitted light.

The emissive metasurface may be configured so that the incident light is either strongly absorbed or back reflected, or generally strongly suppressed the direction of emission.

The emissive metasurface may further comprise another component such as adhesion layers, protection layers, index matching layers, and antireflection layers.

The emissive system is typically chosen to emit light of a desired wavelength.

In an embodiment, the emissive system is located on top of the nanostructured dielectric component.

This may for example be achieved by conformal coating of the nanostructured dielectric component.

The metaatoms of the metasurface may have various shapes. The metaatoms may have the shape of cylinders, truncated cones, truncated pyramids, or cuboids.

The individual shape, i.e., the meta-atom, may be in nanometer size. Thus it may have a size of between about 30 nm to about 300 nm, preferably, of between about 50 nm to about 250 nm, more preferably of between about 90 nm to about 200 nm. The size typically defines the broadest extension of the shape, i.e., the meta-atom.

The dimensions of the metaatoms may be smaller than freespace emission wavelength divided by the refractive index of the dielectric material. Preferably, Δx, Δy, Δz<λ₀/2, where λ₀ is the freespace wavelength, and where Δx, Δy, Δz are the dimensions of a metaatom. This may apply to emission and absorption.

In an embodiment, the refractive index (n=n+ik) of the dielectric nanostructured component is in the range 5>n>2.2, in the range 4>n>2.3, or in the range 3.5>n>2.5, with k<0.1 at absorption and emission wavelength

There are embodiments of the metasurface, wherein the emissive system comprises a ternary or higher order emissive system.

The emissive system may comprise at least one of an organic dye, chromophores, fluorophores, inorganic materials, and quantum dots.

In an embodiment, the emissive system is an organic dye layer. The dye may be a mixture of a chemical substance that chemically bonds to the substrate to which it is applied. Typical dyes are chemical substances that are solved in a solvent, such as water, or organic solvents. The day may be responsible for converting light of a certain first wavelength to light of a certain second wavelength.

Alternatively, the emissive system may comprise an inorganic material. In other words, the emissive system may comprise at least one inorganic molecule, or might consist of at least one inorganic molecule. The at least one inorganic molecule preferably converts light of a certain first wavelength to light of a certain second wavelength. Exemplary inorganic molecules might be quantum dots. An inorganic layer might comprise one type of quantum dots or might comprise a mixture of different quantum dots.

In a preferred embodiment, the at least one emissive system is a chromophore layer. A chromophore layer is a layer that comprises at least one chromophore, or consists of a chromophore. The at least one chromophore preferably converts light of a certain first wavelength to light of a certain second wavelength. A chromophore is the part of a molecule, or the molecule itself that is responsible for the color. The chromophore(s) may be present as pure substances, or may be present in a suitable matrix.

Exemplary chromophores comprise a conjugated pi-system, such as fluorenes, spirofluorenes, spirobifluorenes, quinolines, naphthalines, anthracenes, etc.

A chromophore might be selected from the group consisting of 2,7-Bis(9,9-spirobifluoren-2-yl)-9,9-spirobifluorene (TSBF), (Z)-6-Mesityl-N-(6-mesitylquinolin-2(1H)-ylidene)quinolin-2-amine-BF₂ complex (MQAB), BDP24, and 2,7-Bis(carbazol-9-yl)-9,9-spirobifluorene (Spiro-2CBP).

In an embodiment, the emissive system comprises an emitter and an absorber mixed together in a matrix material.

The absorber and the emitter may be two different molecules. The absorber may for example be acceptor chromophores and the emitter may for example be donor chromophores.

The emitter and the acceptor may be selected so that the absorption and emission peaks of the emissive system are tuned to the resonances of the nanostructure.

By tuning of the concentrations of the emitter and acceptor in the emissive system, the efficiency of the energy transfer, the field distribution inside the emissive system, and the loss by reabsorption may be optimized. For example, donor chromophores may get excited at low wavelength and transfer energy to acceptor chromophores through non-radiative dipole-dipole coupling and the acceptor chromophore may emit at higher wavelength. The non-radiative dipole-dipole coupling may for example be caused by Forster or fluorescence resonance energy transfer (FRET).

This may enhance the overall color conversion efficiency.

There are embodiments provided, wherein the effective refractive index of the emissive system is matched to the resonant nanostructure.

The refractive index n=n+ik of the emissive system at absorption wavelength may be e.g., n=2.0 at k=0.2, and the refractive index n=n+ik of the emissive system at emission wavelength may be n=1.8 at k=0.01.

The dielectric component may comprise a metal oxide or a III-V semiconductor. The III-V semiconductor may for example be GaP, or the like.

In an embodiment, the metal oxide is titanium dioxide.

The metasurface might be placed on a substrate. Typical substrates are glass, SiO₂, sapphire, etc.

The substrate might be relevant as support for the metasurface. Additionally, or alternatively, the substrate might have a technical function, such as stabilizing the metasurface, emitting light, etc. A preferred substrate is glass.

The metasurface is typically placed on the substrate in that way, that the dielectric component is in direct contact with, or in close proximity to the substrate. The dielectric component might be connected with an adhesive layer to the substrate.

The emissive system might be separated by the dielectric component from the substrate.

In cases, wherein the dielectric component is a continuous layer, the emissive system is not in contact with the substrate.

In cases, wherein the dielectric component is not a continuous layer, the emissive system might be in contact with the substrate. In these cases, the substrate might be the support for individual geometric patterns.

Further, there is provided a semiconductor device comprising the metasurface as disclosed herein, the metasurface being configured for enhancement of absorption of a first color and emission of a second color. The semiconductor device may for example be a light-emitting diode (LED).

In the semiconductor device the first color may be blue and second color may be red or green. Furthermore, there is provided a method for preparing a metasurface as disclosed herein, the method comprising the steps:
Providing a dielectric component,
Coating the dielectric component,
Texturing the coating,
Etching the dielectric component, and
Applying an emissive system on the thus obtained nanostructured surface.

The method may further comprise the step of sputtering a metal layer on the dielectric component.

In a first step of the method described herein, a dielectric component is provided. Preferably, the dielectric component corresponds to the dielectric components herein. The dielectric component may be a continuous layer, or may comprise voids.

The dielectric component is preferably provided on a substrate. The substrate preferably corresponds to the substrates described herein. The dielectric component may be connected to the substrate via bonding. The bonding may be a chemical bonding, covalent bonding, ionic bonding, or it may be through an adhesive.

As described, the dielectric component may be a continuous layer and thus completely covers at least one side of the optional substrate. Alternatively, the dielectric component may be discontinuous and comprises voids, thus the optional substrate is not completely covered by the dielectric component on one side.

In a further step, the thickness of the dielectric component may be reduced by applying an appropriate method. The thickness of the component may be reduced by etching, e.g., chemical etching, or physical etching. Preferably, the etching may be carried out with ion beam etching (IBE).

The reduced thickness of the dielectric component may be about 20 to 50%, about 20 to 40%, or about 20 to 30% of the thickness of the provided dielectric component.

Further a metal layer may be applied on the dielectric component. The metal layer may be applied on the provided dielectric component, or on the dielectric component reduced in thickness.

The metal applied may be a transition metal. An example of suitable transition metal is chromium.

The method for applying the metal layer may be any thin layer deposition method: atomic layer deposition, physical vapor deposition (PVD) or sputtering. Thus, in an exemplary embodiment, a chromium layer is sputtered on the dielectric component, either on the provided dielectric component, or on the dielectric component reduced in thickness.

In an embodiment, a metal layer is sputtered on the dielectric component, either reduced in thickness, or as provided.

The metal layer may completely cover the provided dielectric component, or the dielectric component reduced in thickness.

The metal layer may be about 1 to 50%, about 5 to 30%, or about 10 to 20% of the thickness of the provided dielectric component.

In a further step, the dielectric component is coated. In embodiments, wherein a metal layer is present on the dielectric component, the metal layer is coated.

The coating may be a coating that is resistant at least to moisture, oxygen, etc., to avoid the chemical reaction (e.g., oxidation) of the dielectric component, or, if present, of the metal layer.

Thus, preferably, the coating completely covers the dielectric component, or, if present, the metal layer.

The coating may have a thickness of about 10 to 50%, about 15 to 30%, or about 20 to 25% with respect to the thickness of the provided dielectric component.

In a further step, the coating is textured. Texturing in the present case may be defined as introducing a pattern at least in the outermost layer, i.e., the coating. The pattern may be in that way, that there are voids and the layer below the coating is in direct contact with the atmosphere. It is also possible that not only the outermost layer is textured, but also the further layers and thus, layers below the outermost layers are textured. In the latter case also further layers may be in direct contact with the atmosphere.

The texturing may be carried out by appropriate methods. Exemplary methods may be ultraviolet (UV), far ultraviolet (FUV), and extreme ultraviolet (EUV) light exposure using masks, electron beam (EB) exposure, ion beam etching (IBE), reactive ion etching (RIE), etc. The texturing may also be carried out by combining at least two different methods.

The method further comprises the step of etching the dielectric component. In this step, the applied further layers, such as the coating, the optional metal layer, or optional further layers are removed from the dielectric component. Preferably, the substrate is then in direct contact with the atmosphere.

A further embodiment is a metasurface prepared by a method as described herein.

The metasurface disclosed herein may allow a strong enhancement of the light emission and a direction control of the emitted light.

As used herein the term “organic” is used in its generally understood meaning, i.e. it refers to compounds which are carbon-containing compounds. As it is used here, it also includes elemental carbon, at least in the form of fullerenes. The term “organic” is further meant to exclude specific carbon-containing compounds such as: hydrogen-free chalkogenides of carbon, e.g. CO, CO₂, CS₂, and derivatives thereof, e.g. H₂CO₃, KSCN; further excluded are salt-like carbides which are binary compounds of elements with carbon, which decompose to hydrocarbons under the influence of water or dilute acids. Salt-like carbides have the general formula M^{I}₂C₂ or M^{I}C₂, wherein M^{I} or M^{II} denotes a metal ion with one or two valences. Salt-like carbides of calcium, silver and copper decompose to acetylene, the salt-like carbide of aluminium (Al₄C₃) decomposes to methane. Further excluded carbon-containing compound which do not form part of the term “organic” are metallic carbides, which are non-stoichiometric compounds having the character of an alloy. They are resistant to acids and are electrically conducting.

As used here a chromophore is the part of a molecule responsible for its color.

A fluorophore (or fluorochrome, similarly to a chromophore) is a fluorescent chemical compound that can re-emit light upon light excitation.

A phosphor is an emitter emitting phosphorescence. In phosphorescence the emitter does not reemit the radiation it absorbs withion ps- to ns but in μs to s after the absorption of photon. Here organic or inorganic phosphors can be part of the emissive system.

Organic dye is a molecule which contains one or more chromophores/fluorophores or phosphores.

The organic dye can be a small molecule (up to 1000 Da) or a polymer.

Further the emitters can be inorganic phosphors or QDs.

QD as used here are also called (semiconductor) nanocrystals, may be semiconductor particles a few nanometers in size, having optical and electronic properties that differ from those of larger particles as a result of quantum mechanics. The nanocrystals can also be phophors (or phosphorescent QDs).

The matrix as used herein could consist of organic molecules/polymers or could be inorganic. Its main function is to ensure good distribution of the absorbing and the emitting components in the (at least) tri-components or ternary emissive systems.

The emissive system contains a matrix, at least one chromophore, inorganic or hybrid absorber absorber and at least one emisitter (fluorophore or phosphor). The absorbing and the emitting chromophore can be combined in one organic dye/molecule.

In the context of the application, the near-field proximity of a component describes the region of space which is closer to the component than the free-space wavelength of the interacting light fields.

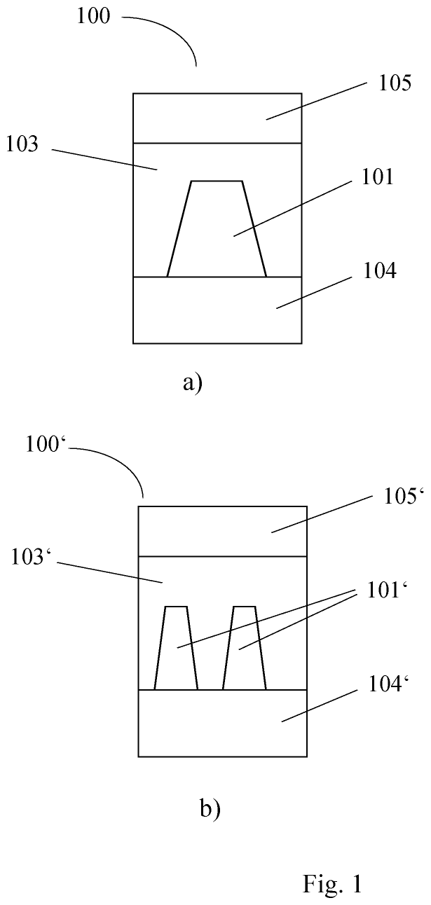

FIG. 1a shows an exemplary metasurface 100. The metasurface 100 comprises a substrate 104, a nanostructured dielectric 101 as dielectric component and an emissive system 103. The air is depicted as 105. There are embodiments, in which more individual geometric patterns of the dielectric layer are present. FIG. 1b shows an embodiment, in which the metasurface 100′ comprises a substrate 104′, two dielectric cones 101′ and an emissive system 103′. The air is depicted as 105′. For embodiments according to FIG. 1b, an embodiment of FIG. 1a might be called metaatom.

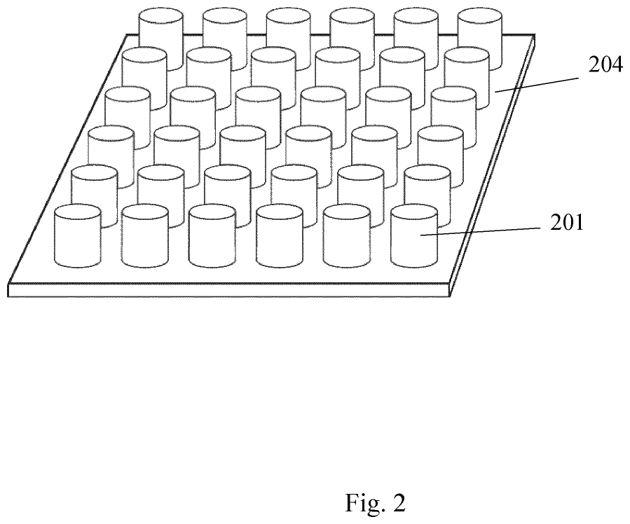

FIG. 2 shows a periodic arrangement of dielectric disks 201 on a substrate 204. The dielectric disks 201 form nanoantenas/or resonators in the nanostructured dielectric layer.

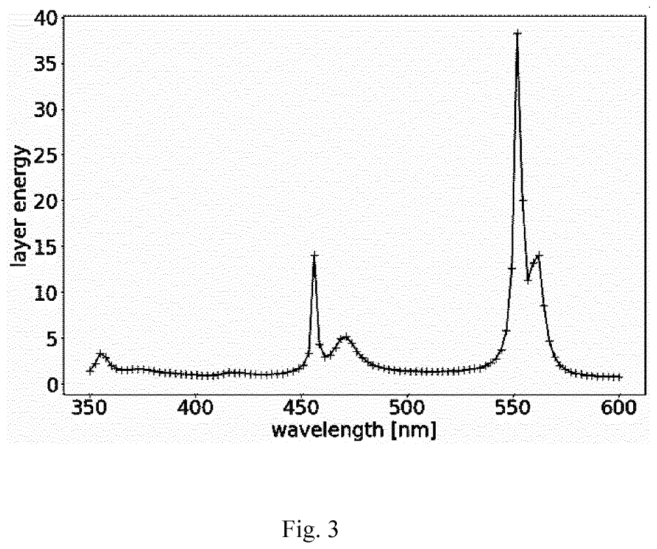

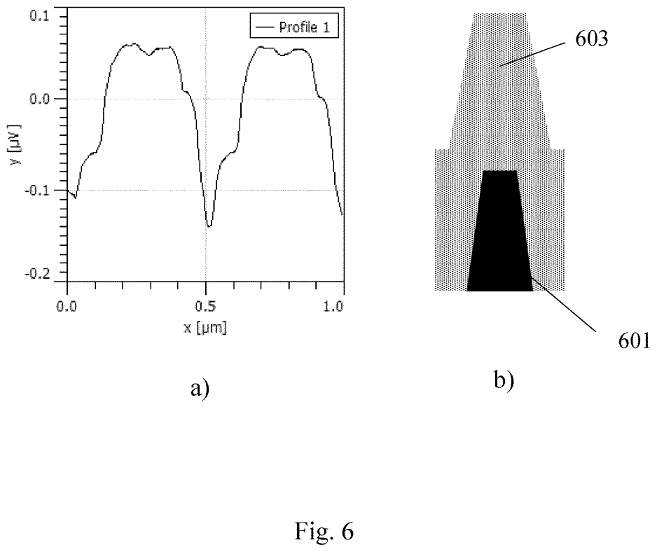

FIG. 3 (see also FIG. 6) shows a simulated wavelength dependence of the electric field energy in the emissive system as placed around the dielectric TiO₂ nanostructures (normalized to the electric field energy in the same volume of the emissive layer and absent TiO₂ structure). In the example of FIG. 3, TiO₂ provided as a dielectric component structured into nanocones (the dielectric nanoantenas) has been identified as well-suited low-loss material for blue excitation and green emission system. The simulations were done using JCMSuite+Python and the reciprocity principle has been applied (i.e., simulations were done for “incident emission”). For the simulation, the emissive metasurface consists of nan-cone shaped TiO₂ nanostructures covered with an emissive system. The combination of the TiO₂ nanostructures and the emissive system together might form the emissive metasurface. The meta-atoms/nanoantenas of the emissive metasurface are accordingly consistent of the dielectric TiO₂ nanostructures with the emissive system. The emissive system as combined is with thickness/dimensions to fit the metasurface definitions. A matching of lattice modes to the localized meta-atom resonances was applied. The cone/metaatom dimensions were optimized for strong resonances at both selected excitation and emission wavelengths. Period and meta-atom (in this case discs or tryncated cones) dimensions were derived by iterative lattice mode matching with the following lattice modes equations:

$$\frac{2 π}{λ} = \sqrt{{( \frac{2 π}{λ} sin θ cos ϕ + p \frac{2 π}{a} )}^{2} + {( \frac{2 π}{λ} sin θ sin ϕ + j \frac{2 π}{a} )}^{2}} \qquad ( 1 )$$

$$n \frac{2 π}{λ} = \sqrt{{( \frac{2 π}{λ} sin θ cos ϕ + l \frac{2 π}{a} )}^{2} + {( \frac{2 π}{λ} sin θ sin ϕ + m \frac{2 π}{a} )}^{2}} \qquad ( 2 )$$

The iterative matching of lattice mode to Mie-type resonances were done according to ACS Photonics 2018 (5), 1359 with the following steps:
1. Choose angles of incidence θ and Φ
2. Choose diffraction orders (p, j, l, and m) (for chosen θ and Φ with initial lattice period a) for close match of either one of the two equations.
3. Tune period a to satisfy the lattice mode equation completely.
4. Retune disc geometries using new a to have simulated Mie-resonance at chosen emission wavelength.

As is shown, strong resonances of the emissive metasurface were found at both absorption and emission wavelengths for square symmetric periodic nano-cone structure of TiO₂/emitter system metasurface Electric fields are concentrated inside the emissive system part of the metasurface (and further inside the TiO₂ nano-cones). The field energies inside the emissive system are enhanced by a factor of up to 40 for the metasurface as compared to an unstructured reference (which is the emissive system onto a flat dielectric layer of the same dielectric).

The simulation parameters are as follows: infinite periodic truncated TiO₂ cone structure with a square period P=308 nm and upper and lower cone diameters of D=100 nm and D=232 nm, respectively. Height of TiO₂ cones: 180 nm. Substrate: glass (Borofloat 33). Emissive layer height: 250 nm. Excitation: plane wave along the normal of the surface of the substrate.

Whereas the left y-axis refers to the optical density (OD), the right y-axis refers to the emission, calculated in counts per second. The thinner line shows the optical density and the thicker line refers to the emission.

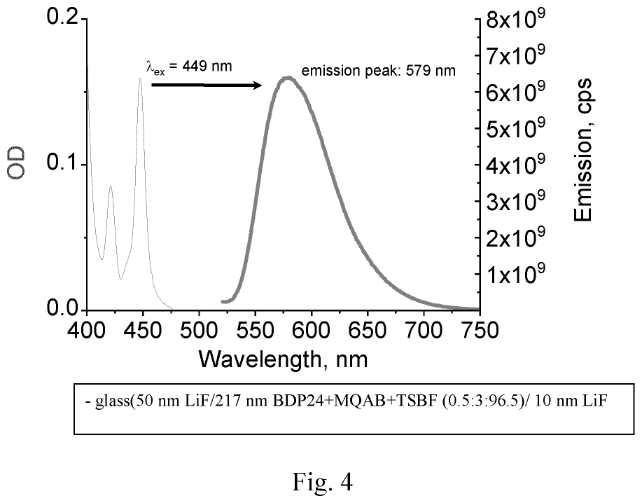

FIG. 4 shows the measured optical density and emission spectrum of a 217 nm thick unstructured organic film on a glass substrate. The example is a glass substrate, covered with a 50 nm layer of LiF, a 217 nm thick emissive layer of BDP24 (emitter)+MQAB (absorber)+TSBF (matrix), vacuum vapor evaporated simultaneous with a volume ratio of 0.5 to 3 to 96.5, of BDP24+MQAB+TSBF, respectively, covered with a 10 nm thick layer of LiF. Efficient energy transfer from the donor (MQAB) to the acceptor (BDP24) is achieved for excitation at 450 nm with peak emission at 579 nm. Whereas the left y-axis refers to the optical density (OD), the right y-axis refers to the emission, calculated in counts per second. The thinner line shows the optical density, and the thicker line refers to the emission

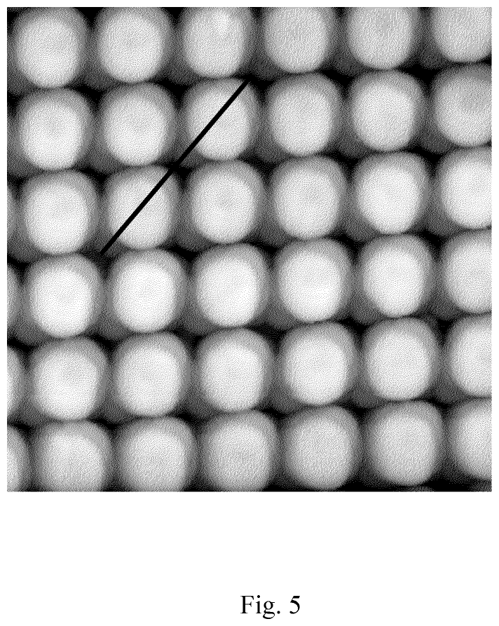

FIG. 5 shows the topography [as measured by atomic force microscopy (AFM)] of an emissive layer evaporated on top of a nanostructured TiO₂ sample. The image size is 2 μm×2 μm. The height of the topography is depictured as a 200 nm grayscale. TiO₂ meta-atoms are embedded in the emissive layer. There was no crystallization of the emissive layer observed.

FIG. 6 shows the profile structure of an emissive layer evaporated on a nanostructured TiO₂ sample, taken from the FIG. 5 topography along the straight line. FIG. 6a shows a measured profile. FIG. 6b shows a schematic profile of TiO₂ layer (601) and an emissive layer (603).

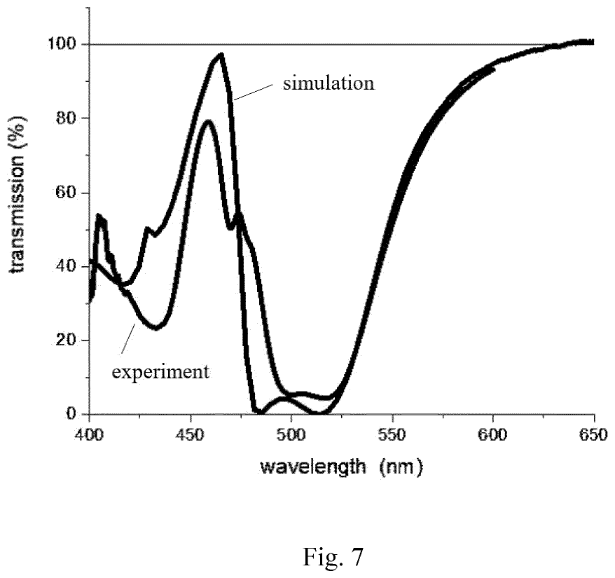

FIG. 7 shows the transmission spectra of a metasurface in experiment vs. simulation. The transmission spectra allow to determine effective metasurface geometries, such as metasurface patterns, by matching of simulated to measured transmission spectra.

The simulation parameters were as follows: infinite periodic truncated TiO₂ cone structure with a square period P=290 nm and upper and lower cone diameters of D=260 nm and D=246 nm, respectively. Height of TiO₂ cones: 180 nm. Substrate: glass (Borofloat 33).

### Simulation Tools:

### Full Wave FEM Simulations for Transmission Spectra

Transmission spectra are calculated by unit cell FEM simulations of the periodic metasurface illuminated by a perpendicular plane wave and using Fourier transformations for the far fields. The numerical aperture of the simulations is set to the NA of the objective used for measuring the transmission spectra.
Effective period and cone diameters are determined by fitting the simulated to measured spectra for uncoated samples.
Effective emissive layer film thicknesses are determined by fitting of simulated to measured spectra coated samples.

As can be seen, the correlation of simulation and experiment is very good.

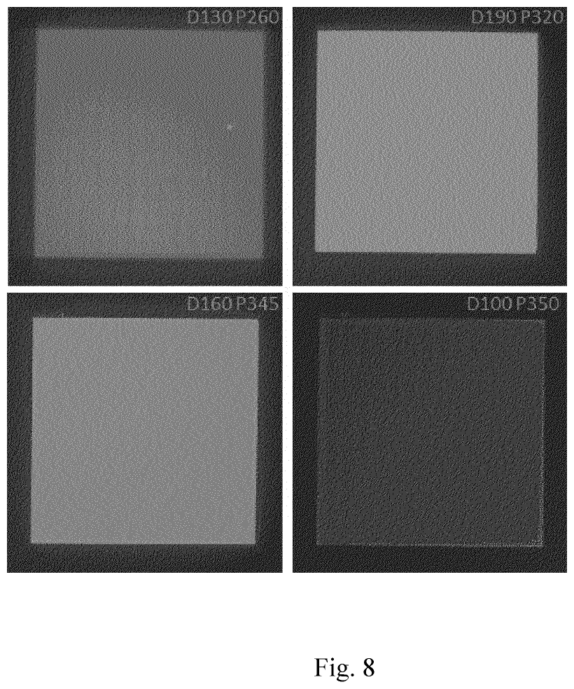

FIG. 8 shows TiO₂ dialectric nanostructures based metasurfaces: emitting metasurface with vs. flat film correlation in fluorescence microscopy. The brighter inner squares (of size 0.5 mm×0.5 mm) correspond to the metasurfaces, whereas the darker frames are the flat film, i.e., the area without the TiO₂, but with the same emissive system. “D” gives the upper cone diameters in nm of the truncated cones and “P” the size of the periodic meta-atoms in nm. A strong field dependent amplification of emission is observed with fluorescence microscopy (using a 10× objective with NA of 0.45, a filter cube with band pass filter 473 nm to 491 nm for the white light excitation and an excitation blocking 499 nm long pass filter for the transmitted light). The “D130 P260” metasurface emits green light, the “D190 P320” metasurface emits yellow light, the “D160 P345” metasurface emits yellow-red light, and the “D100 P350” metasurface emits red light (colors not shown).

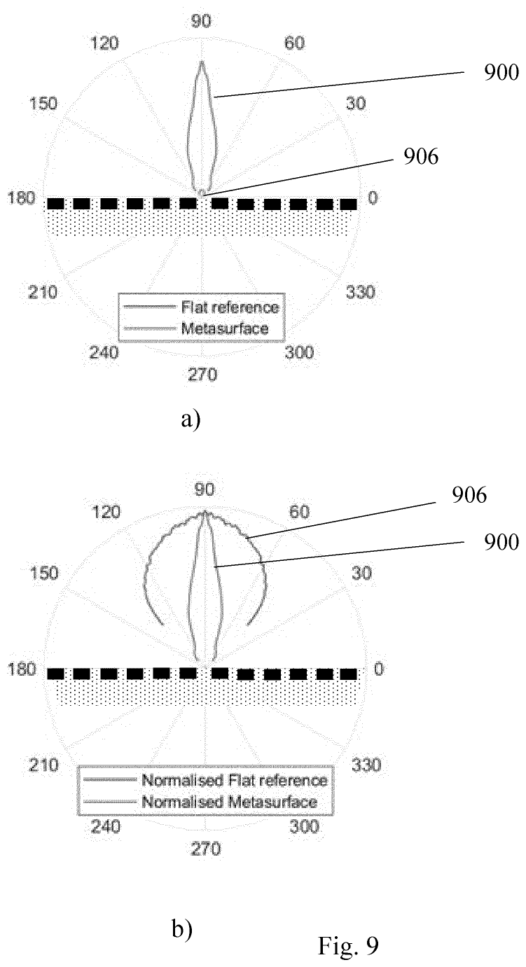

FIG. 9 shows the measured emission intensity of an emissive metasurface, as a function of polar angle, excited by a laser beam (with wavelength of 445 nm) along the normal of the substrate.

The metasurface corresponds to an example as depicted in FIG. 1a and comprises TiO₂ cones with a top diameter of approx. 160 nm. The periodic element, i.e., the meta-atom, comprising one TiO₂ cone has an expansion P of 320 nm. FIG. 9a compares the intensity of a metasurface (900) to that of a flat reference (906), i.e., the intensity of an unstructured emissive layer without any TiO₂ structures. FIG. 9b compares the two intensity of FIG. 9a both normalized to the intensity at normal emission.

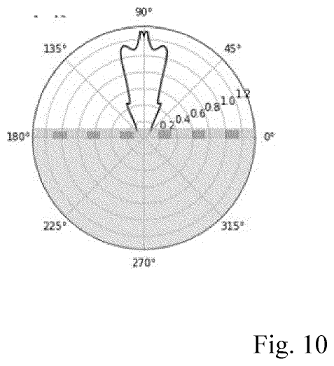

FIG. 10 shows the simulation result for the system described in FIG. 9. Angle-resolved emission simulations were based on reciprocity principle and geometries of the metasurface were matched with experiment.

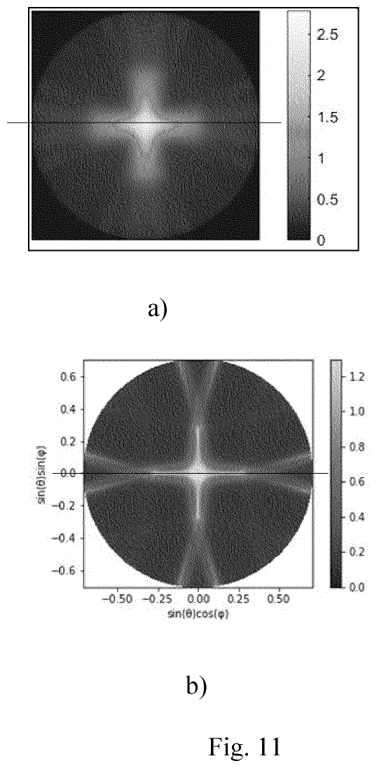

FIG. 11 shows the field intensities of measured and simulated angle-resolved metasurface simulations. FIG. 11a shows the experimental results measure by back-focal-plane imaging, whereas FIG. 11b shows the results obtained by simulation. The setup corresponds to the setup of the results shown in FIGS. 9 and 10.

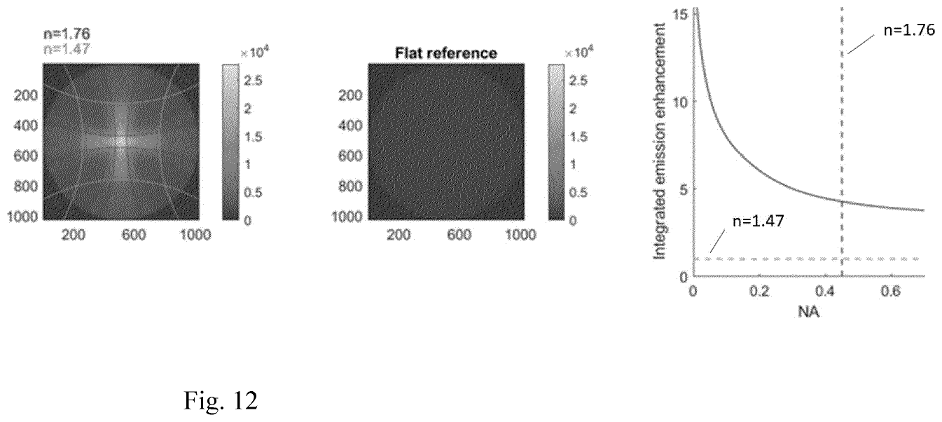

FIG. 12 shows the match of the angle-resolved emission simulations based on reciprocity principle with experiment. Strong directional emission enhancement was observed. An enhancement of more than 15 for perpendicular emission and an enhancement of about 5 for the NA of the Zeiss microscope objective was observed. As can be seen, there is a very good match to simulations and lattice mode formula.

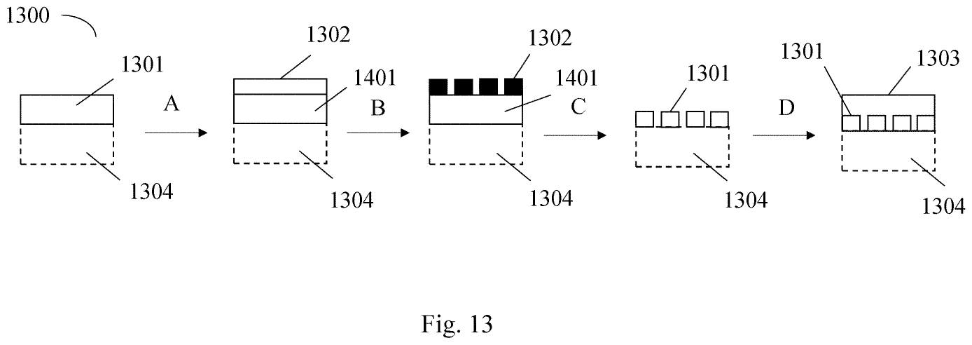

FIG. 13 shows a general method for preparing a metasurface 1300. Provided was a dielectric layer (1301, that was optionally placed on a substrate 1304. In step A, the dielectric layer 1301 was covered with a coating 1302. In step B, the coating 1302 was textured. In step C, the dielectric layer 1301 was etched. The coating 1302 may also be removed in a previous intermediate step, or in this step C. In step D, an emissive system 1303 was applied on the thus obtained structured surface. The emissive system 1303 may be applied by evaporation.

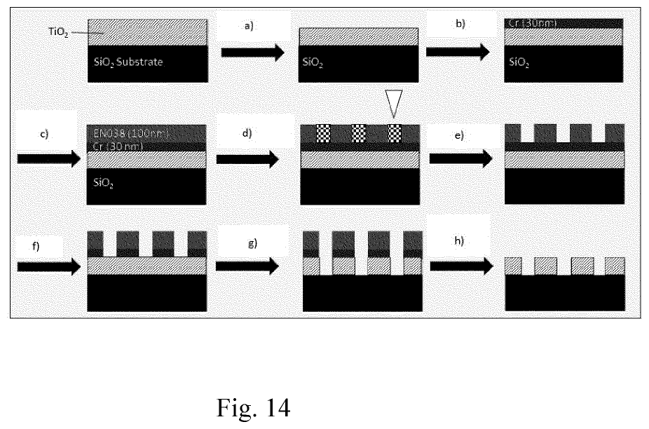

FIG. 14 shows an exemplary method for preparing a dielectric layer on a substrate. A SiO₂ substrate covered with a TiO₂ dielectric layer was provided. In the shown embodiment, the TiO₂ dielectric layer has a thickness of 570 nm. In step a) TiO₂ ion beam etching (IBE) was carried out and the TiO₂ layer was reduced in thickness to a thickness of 180 nm. In step b) a chromium layer was sputtered on the TiO₂ layer. The chromium layer has a thickness of 30 nm. In step c) a resistant coating EN038 was applied on the chromium layer. The resistant coating has a thickness of 100 nm. In subsequent step d) an electron beam (EB) was applied to the coating and voids appeared, the coating was thus textured. In the further development, in step e), the voids in the coating were present. In subsequent step f) voids were prepared via ion beam etching and the TiO₂ layer was in direct contact with the atmosphere. In subsequent step g) reactive ion etching (RIE) was applied and voids in the TiO₂ layer were present. In a further step h) the chromium layer was etched and through the application of a solvent, such as acetone, the coating was removed. Thus, a substrate comprising a TiO₂ pattern (such as TiO₂ cones) was prepared.

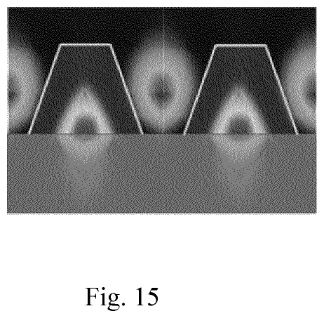

FIG. 15 shows the simulated field intensity at 550 nm wavelengths of a TiO₂ cone as dielectric layer on SiO₂ as substrate and with an emissive layer. The experimental setup is depicted in FIG. 1a. Details on the geometries are given in the text to FIG. 3. Strong concentration of the electric field in the emissive layer can be seen.

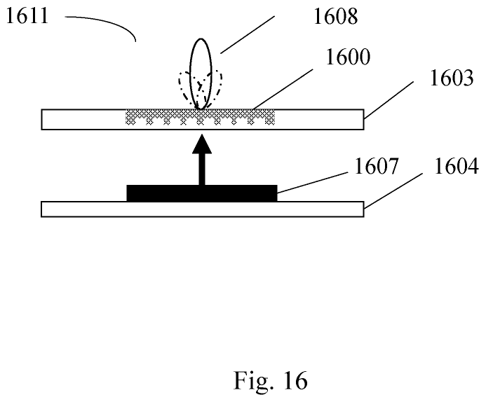

FIG. 16 shows an exemplary LED color conversion filter 1611. The LED color conversion filter 1611 comprises a substrate 1604 and a blue emission layer 1607 placed on the substrate 1604. The light emitted from the blue emission layer 1607 passes through the emissive system (1603) comprising the metasurface 1600. The emission 1608 is in the desired wavelength and the desired direction, as the metasurface 1600 may convert the light and direct the emitted light. Furthermore, the emission 1608 might be enhanced.

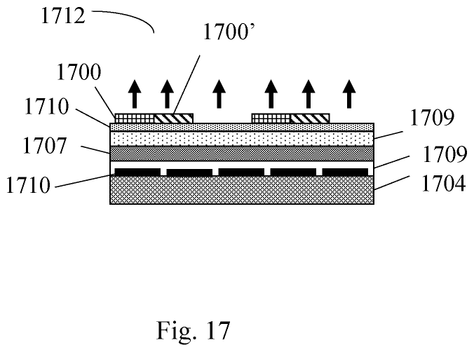

FIG. 17 shows an exemplary semiconductor device 1712. The semiconductor device 1712 comprises a substrate 1704, such as a TFT substrate. The semiconductor device 1712 further comprises charge transport layers 1709 and electrodes 1710. The semiconductor device 1712 also comprises a blue emission layer 1707. The semiconductor device 1712 further comprises metasurfaces 1700, 1700′. The metasurfaces might convert the light emitted from the blue emission layer to different wavelengths. Thus, the semiconductor device 1712 might emit light of converted wavelengths and of light of the blue emission layer 1707. The combination of the blue light and of the converted light corresponds to light of the desired color.

The embodiments may also comprise:

[1] An emissive metasurface (100, 100′, 400, 900, 1600, 1700, 1700′) comprising a nanostructured dielectric component (101, 101′, 201, 601, 1301) and an emissive system (103, 103′, 603, 1303, 1603), wherein the nanostructured dielectric component (101, 101′, 201, 601, 1301) comprises a plurality of metaatoms, and wherein the emissive system (103, 103′, 603, 1303, 1603) is configured to absorb and emit light in the visible range, and wherein the metaatoms are configured so that they resonantly match with the frequency of the light absorbed and emitted by the emissive system (103, 103′, 603, 1303, 1603).

[2] The metasurface (100, 100′, 400, 900, 1600, 1700, 1700′) according to [1], with the emissive system (103, 103′, 603, 1303, 1603) is at least partially in the near-field proximity to the nanostructured dielectric component (101, 101′, 201, 601, 1301).

[3] The metasurface (100, 100′, 400, 900, 1600, 1700, 1700′) according to [1] or [2], wherein the metaatoms are arranged such that they support at least one lattice resonance mode and wherein the metaatoms have a size and shape such that they support at least one further resonance mode.

[4] The metasurface according to any of [1] to [3], wherein the nanostructured dielectric component (101, 101′, 201, 601, 1301) is configured so that a first localized resonance mode of the metaatoms and a lattice resonance mode of the nanostructured dielectric component (101, 101′, 201, 601, 1301) are matched to the emission frequency of the emissive system (103, 103′, 603, 1303, 1603), and so that a second localized resonance mode of the metaatoms is matched to the absorption frequency of the emissive system (103, 103′, 603, 1303, 1603).

[5] The metasurface according to any of [1] to [4], wherein the nanostructured dielectric component (101, 101′, 201, 601, 1301) and the emissive system (103, 103′, 603, 1303, 1603) are configured to resonantly enhance the absorption of the emissive system (103, 103′, 603, 1303, 1603).

[6] The metasurface according to any of [1] to [5], wherein the nanostructured dielectric component (101, 101′, 201, 601, 1301) and the emissive system system (103, 103′, 603, 1303, 1603) are configured to resonantly enhance the emission of the emissive system system (103, 103′, 603, 1303, 1603).

[7] The metasurface according to any of [1] to [6], wherein the emissive metasurface is configured for directional intensity control of emitted light.

[8] The metasurface according to any of [1] to [7], wherein the emissive metasurface is configured so that the incident light is either strongly absorbed or back reflected, or generally strongly suppressed the direction of emission.

[9] The metasurface according to any of [1] to [8], wherein the emissive metasurface further comprises another component such as adhesion layers, protection layers, index matching layers, or antireflection layers.

[10] The metasurface according to any of [1] to [9], wherein the emissive system (103, 103′, 603, 1303, 1603) is located on top of the nanostructured dielectric component (101, 101′, 201, 601, 1301).

[11] The metasurface according to any of [1] to [10], wherein the metaatoms have the shape of cylinders, truncated cones, truncated pyramids, cuboids, truncated balls or other 3D shapes are produced by design

[12] The metasurface according to any of [1] to [11], wherein the dimensions of the metaatoms are smaller than half the freespace wavelength of the emission.

[13] The metasurface according to any of [1] to [12], wherein the refractive index (n=n+ik) of the dielectric nanostructured component (101, 101′, 201, 601, 1301) is in the range 5>n>2.2, in the range 4>n>2.3, or in the range 3.5>n>2.5, with k<0.1 at absorption and emission wavelength.

[14] The metasurface according to any of [1] to [13], wherein the emissive system (103, 103′, 603, 1303, 1603) comprises a ternary or higher number of components emissive system (103, 103′, 603, 1303, 1603).

[15] The metasurface according to any of [1] to [14], wherein the emissive system (103, 103′, 603, 1303, 1603) comprises at least one of the following: organic dyes (chromophores as absorbers and fluorophoresor phosphors as emitters) as well as inorganic absorbers and emitters including quantum dots.

[16] The metasurface according to any of [1] to [15], wherein the emissive system (103, 103′, 603, 1303, 1603) is a combination of organic matrix and inorganic absorbers and/or emitters and other way around—inorganic matrix with organic absorbers/emitters.

[17] The metasurface according to any of [1] to [16], wherein the emissive system (103, 103′, 603, 1303, 1603) comprises at least one component as an emitter and at least one component as an absorber mixed together in a matrix material.

[18] The metasurface according to [17], wherein the absorber and the emitter are two different organic dyes/molecules.

[19] The metasurface according to [17] or [18], wherein the emitter and the absorber are selected so that the absorption and emission peak wavelengths of the emissive system (103, 103′, 603, 1303, 1603) are tuned to the resonances of the TiO2 nanostructures and if needed to the resonances of the TiO2/emitter system combined nanostructures/meta-atoms

[20] The metasurface according to any of [17] to [19], wherein, by tuning of the concentrations of the emitter and absorber in the emissive system (103, 103′, 603, 1303, 1603), the efficiency of the energy transfer, the field distribution inside the emissive system (103, 103′, 603, 1303, 1603), are optimized and the loss by reabsorption is diminished.

[21] The metasurface according to any of [1] to [20], wherein the absorption coefficient of the emissive system (103, 103′, 603, 1303, 1603) is tuned to ensure highly resonant meta-atoms/local resonances and ensure and good matching to the lattice modes.

[22] The metasurface according to any of [1] to [21], wherein the refractive index n=n+ik of the emissive system at absorption wavelength is n=2.0 at k=0.2, and the refractive index n=n+ik of the emissive system (103, 103′, 603, 1303, 1603) at emission wavelength is n=1.8 at k=0.01.

[23] The metasurface according to any of [1] to [22], wherein the dielectric component (101, 101′, 201, 601, 1301) comprises a metal oxide or a III-V semiconductor.

[24] The metasurface according to [23], wherein the metal oxide is titanium dioxide.

[25]A semiconductor device comprising the metasurface of any of [1] to [24], the metasurface being configured for enhancement of absorption of a first color and emission of a second color.

[26] The semiconductor device of [25], wherein the first color is blue and second color is red or green.

[27]A method for preparing a metasurface (1300) according to any of [1] to [23], the method comprising the steps:
Providing a dielectric component (101, 101′, 201, 601, 1301),
Coating the dielectric component (101, 101′, 201, 601, 1301),
Texturing the coating,
Etching the dielectric component (101, 101′, 201, 601, 1301), and
Applying an emissive system (103, 103′, 603, 1303, 1603) on the thus obtained nanostructured surface.

[28] The method according to [27], further comprising the step of sputtering a metal layer on the dielectric component (101, 101′, 201, 601, 1301).

### LIST OF REFERENCE SIGNS

100, 100′, 400, 900, 1600, 1700, 1700′ metasurface
101, 101′, 201, 601, 1301 dielectric layer
1302 coating
103, 103′, 603, 1303, 1603 emissive system
104, 104′, 204, 1304, 1604, 1704 substrate
105, 105′ air
906 flat reference
1300 method for preparing a metasurface
1607, 1707 blue emission layer
1608 emission
1611 LED color conversion filter
1709 charge transport layers
1710 electrode
1712 semiconductor device

1. An emissive metasurface comprising a nanostructured dielectric component and an emissive system, wherein the nanostructured dielectric component comprises a plurality of metaatoms, and wherein the emissive system is configured to absorb and emit light in the visible range, and wherein the metaatoms are configured so that they resonantly match with the frequency of the light absorbed and emitted by the emissive system.

2. The metasurface according to claim 1, with the emissive system is at least partially in the near-field proximity to the nanostructured dielectric component.

3. The metasurface according to claim 1, wherein the metaatoms are arranged such that they support at least one lattice resonance mode and wherein the metaatoms have a size and shape such that they support at least one further resonance mode.

4. The metasurface according to claim 1, wherein the nanostructured dielectric component is configured so that a first localized resonance mode of the metaatoms and a lattice resonance mode of the nanostructured dielectric component are matched to the emission frequency of the emissive system, and so that a second localized resonance mode of the metaatoms is matched to the absorption frequency of the emissive system.

5. The metasurface according to claim 1, wherein the nanostructured dielectric component and the emissive system layer are configured to resonantly enhance the absorption of the emissive system.

6. The metasurface according to claim 1, wherein the nanostructured dielectric component and the emissive system layer are configured to resonantly enhance the emission of the emissive system.

7. The metasurface according to claim 1, wherein the emissive metasurface is configured for directional intensity control of emitted light.

8. The metasurface according to claim 1, wherein the emissive metasurface is configured so that the incident light is either strongly absorbed or back reflected, or generally strongly suppressed the direction of emission.

9. The metasurface according to claim 1, wherein the emissive metasurface further comprises another component such as adhesion layers, protection layers, index matching layers, or antireflection layers.

10. The metasurface according to claim 1, wherein the emissive system is located on top of the nanostructured dielectric component.

11. The metasurface according to claim 1, wherein the metaatoms have the shape of cylinders, truncated cones, truncated pyramids, or cuboids.

12. The metasurface according to claim 1, wherein the dimensions of the metaatoms are smaller than half the freespace wavelength of the emission.

13. The metasurface according to claim 1, wherein the refractive index (n=n+ik) of the dielectric nanostructured layer is in the range 5>n>2.2, in the range 4>n>2.3, or in the range 3.5>n>2.5, with k<0.1 at absorption and emission wavelength.

14. The metasurface according to claim 1, wherein the emissive system comprises a ternary or higher order emissive system.

15. The metasurface according to claim 1, wherein the emissive system comprises at least one of an organic dye, chromophores, fluorophores, inorganic materials, and quantum dots.

16. The metasurface according to claim 1, wherein the emissive system comprises an emitter and an acceptor mixed together in a matrix material.

17. The metasurface according to claim 16, wherein the absorber and the emitter are two different molecules.

18. The metasurface according to claim 16, wherein the emitter and the absorber are selected so that the absorption and emission peak wavelengths of the emissive system are tuned to the resonances of the nanostructure.

19. The metasurface according to claim 16, wherein, by tuning of the concentrations of the emitter and absorber in the emissive system, the efficiency of the energy transfer, the field distribution inside the emissive system, and the loss by reabsorption are optimized.

20. The metasurface according to claim 1, wherein the effective refractive index of the emissive system is matched to the resonant nanostructure.

21-27. (canceled)
